(19) United States
(12) Patent Application Publication
(10) Pub. No.: US 2025/0318197 A1
(43) Pub. Date: Oct. 9, 2025

(54) SEMICONDUCTOR DEVICE AND FABRICATING METHOD THEREOF

(71) Applicant: Fujian Jinhua Integrated Circuit Co., Ltd., Quanzhou City (CN)

(72) Inventors: XUANTONG CHEN, Quanzhou City (CN); Chien-Cheng Tsai, Quanzhou City (CN); Yang Zhou, Quanzhou City (CN)

(73) Assignee: Fujian Jinhua Integrated Circuit Co., Ltd., Quanzhou City (CN)

(21) Appl. No.: 18/826,125

(22) Filed: Sep. 5, 2024

(30) Foreign Application Priority Data
Apr. 9, 2024 (CN) 202410423823.9

(51) Int. Cl. H01L 29/49; H01L 29/66; H01L 29/786

(52) U.S. Cl. CPC H10D 30/6739; H10D 30/031; H10D 30/6728; H10D 30/6757

(57) ABSTRACT

A semiconductor device includes a source electrode, a drain electrode, a gate electrode, a channel structure, a gate dielectric layer, a barrier layer and an upper dielectric layer. The source electrode, the gate electrode, and the drain electrode are disposed in sequence. The channel structure is disposed between the drain electrode and the source electrode and is connected the drain electrode and the source electrode. The gate dielectric layer is disposed between the channel structure and the gate electrode. The barrier layer is disposed between the gate electrode and the gate dielectric layer. The upper dielectric layer is disposed between the drain electrode and the source electrode, and which includes a protrusion protruding toward the channel structure and sandwiched between the gate electrode and the drain electrode. The protrusion at least covers a part of a top surface of the barrier layer.

### BACKGROUND OF THE INVENTION

### 1. Field of the Invention

The present disclosure relates to a semiconductor device and a fabricating method thereof, and more particularly, to a semiconductor device including a vertical channel structure and a fabricating method thereof.

### 2. Description of the Prior Art

The development of semiconductor integrated circuit technology progresses continuously and circuit designs in products of the new generation become smaller and more complicated than those of the former generation. The amount and the density of the functional devices in each chip region are increased constantly according to the requirements of innovated products, and the size of each device has to become smaller accordingly. The conventional planar metal-oxide-semiconductor (MOS) transistor has difficulty when scaling down in the development of the semiconductor device. Therefore, the stereoscopic transistor technology or the non-planar transistor technology that allows smaller size and higher performance is developed to replace the planar MOS transistor for reducing the dimension of the transistor unit and/or improving the operation performance of the transistor unit.

### SUMMARY OF THE INVENTION

One of the objectives of the present disclosure is to provide a semiconductor device and a method of fabricating the same, where a barrier is disposed between a gate dielectric layer and a gate electrode, to prevent a gate dielectric layer from directly contacting the metal and easily producing high-resistance products, and to improve the operation performance of the semiconductor device thereby.

To achieve the purpose described above, one embodiment of the present disclosure provides a semiconductor device includes a source electrode, a drain electrode, a gate electrode, a channel structure, a gate dielectric layer, a barrier layer and an upper dielectric layer. The source electrode and the drain electrode are disposed in sequence. The gate electrode is disposed between the drain electrode and the source electrode. The channel structure is disposed between the drain electrode and the source electrode and is connected the drain electrode and the source electrode.

The gate dielectric layer is disposed between the channel structure and the gate electrode. The barrier layer is disposed between the gate electrode and the gate dielectric layer. The upper dielectric layer is disposed between the drain electrode and the source electrode, and which includes a protrusion protruding toward the channel structure and sandwiched between the gate electrode and the drain electrode. The protrusion at least covers a part of a top surface of the barrier layer.

To achieve the purpose described above, one embodiment of the present disclosure provides a fabricating method of a semiconductor device including the following steps. A source electrode, a gate electrode, and a drain electrode stacked in sequence are formed. A channel structure is formed between the drain electrode and the source electrode, and is connected the drain electrode and the source electrode. A gate dielectric layer is formed between the channel structure and the gate electrode. An upper dielectric layer is formed between the drain electrode and the source electrode. The gate electrode is formed within the upper dielectric layer, and the upper dielectric layer includes a protrusion protruding toward the channel structure and sandwiched between the gate electrode and the drain electrode. The gate electrode is under the protrusion.

Overall speaking, according to the semiconductor device and the fabricating method thereof, a protrusion is additionally formed on the upper dielectric layer which is disposed between the drain electrode and gate electrode, with the protrusion being protruding toward the channel structure. Then, the forming position of the barrier layer will be self-aligned with the protrusion of the upper dielectric layer, to effectively isolate the gate dielectric layer from metal materials. In this way, the arrangement of the barrier layer enables to prevent the dielectric material of the gate dielectric layer from directly contacting the metal material of the gate electrode and easily producing high-resistance products, and to improve the functions and performance of the gate electrode and the channel structure, so as to optimize the operation and the function of the semiconductor device thereby.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a cross-sectional schematic diagram illustrating a semiconductor device according to a first embodiment of the present disclosure.

FIG. 2 to FIG. 8 are schematic diagrams illustrating a fabricating method of a semiconductor device according to an embodiment of the present disclosure, wherein:

FIG. 2 is a schematic cross-sectional view of a semiconductor device after forming a gate electrode;

FIG. 3 is a schematic cross-sectional view of a semiconductor device after forming a barrier material layer;

FIG. 4 is a schematic cross-sectional view of a semiconductor device after forming a barrier layer;

FIG. 5 is a schematic cross-sectional view of a semiconductor device after forming a dielectric material layer;

FIG. 6 is a schematic cross-sectional view of a semiconductor device after forming a semiconductor material layer;

FIG. 7 is a schematic cross-sectional view of a semiconductor device after forming a channel structure; and

FIG. 8 is a schematic cross-sectional view of a semiconductor device after forming a drain electrode.

FIG. 9 is a cross-sectional schematic diagram illustrating a semiconductor device according to a second embodiment of the present disclosure.

FIG. 10 is a cross-sectional schematic diagram illustrating a semiconductor device according to a third embodiment of the present disclosure.

### DETAILED DESCRIPTION

To provide a better understanding of the presented invention, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

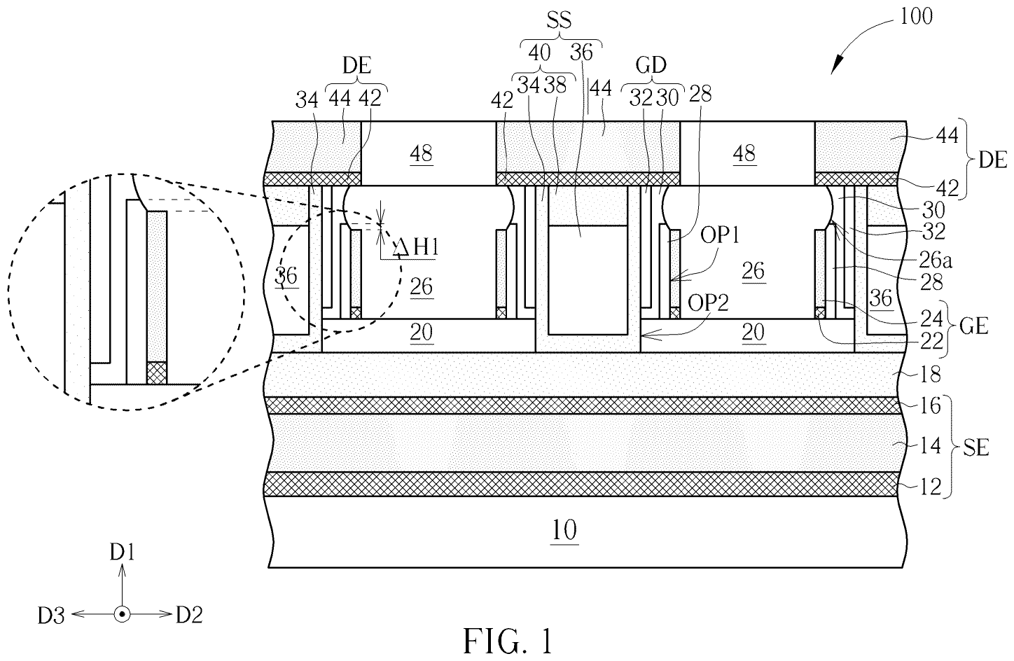

Please refer to FIG. 1. FIG. 1 is a cross-sectional schematic drawing illustrating a semiconductor device 100 according to a first embodiment of the present disclosure. As shown in FIG. 1, the semiconductor device 100 includes a source electrode SE, a drain electrode DE, a gate electrode GE, a channel structure SS, a gate dielectric layer GD, a barrier layer 28, and an upper dielectric layer 26. The drain electrode DE and the source electrode SE are stacked one over another in a vertical direction D1, and the gate electrode GE is disposed on the source electrode SE, between the drain electrode DE and the source electrode SE. The channel structure SS is partially disposed in the gate electrode GE, and also between the drain electrode DE and the source electrode SE in the vertical direction D1 to electrically connect the drain electrode DE and the source electrode SE. The upper dielectric layer 26 is disposed between the drain electrode DE and the source electrode SE in the vertical direction D1, and the gate electrode GE is disposed in the upper dielectric layer 26. The gate dielectric layer GD and the barrier layer 28 are also disposed in the upper dielectric layer 26, and is between the channel structure SS and the gate electrode GE in a horizontal direction D2 or a horizontal direction D3 opposite to the horizontal direction D2. The barrier layer 28 is disposed between the gate electrode GE and the gate dielectric layer GD, to isolate the gate dielectric layer GD from directly contacting metal materials to product high-resistance products.

It is noted that, the upper dielectric layer 26 includes a protrusion 26a extending toward the channel structure SS, with the protrusion being sandwiched between the drain electrode DE and the gate electrode GE. The protrusion 26a at least covers a portion of the top surface of the barrier layer 28, to further isolate the gate dielectric layer GD from directly contacting the metal materials. Through the arrangement of the upper dielectric layer 26, the location of the barrier layer 28 is self-aligned with the protrusion 26a of the upper dielectric layer 26, such that, the barrier layer 28 enables to effectively isolate the gate dielectric layer GD from contacting the metal material. Accordingly, it is sufficient to avoid the gate dielectric layer GD from reacting with the metal material of the gate electrode GE to product high-resistance products, so as to improve the component performance of the gate electrode GE and the channel structure SS, and to enhance the operation of the semiconductor device 100. In one embodiment, the barrier layer 28 for example includes titanium (Ti), titanium nitride (TiN), tantalum (Ta), tantalum nitride (TaN), tungsten nitride (WN), or other suitable metal barrier materials, and preferably includes titanium nitride, but not limited thereto.

Precisely speaking, as shown in FIG. 1, the protrusion 26a partially covers the top surface of the barrier layer 28. Also, since a boundary between the protrusion 26a and the gate electrode GE has a recess portion, the barrier layer 28 is further filled in the recess portion, and the gate dielectric layer GD covers a rest portion of the top surface of the barrier layer 28. The gate dielectric layer GD further includes a first dielectric layer 30 disposed between the barrier layer 28 and the channel structure SS in the horizontal direction D2, and a second dielectric layer 32 disposed over the first dielectric layer 30 in the vertical direction D1, and between the first dielectric layer 30 and the channel structure SS in the horizontal direction D2. The first dielectric layer 30 is filled up the rest space of the recess portion, and the second dielectric layer 32 covers the sidewalls of the first dielectric layer 30 in an uniform manner. In one embodiment, the first dielectric layer 30 and the second dielectric layer 32 for example both include a dielectric material like silicon oxide, silicon nitride, silicon oxynitride, silicon carbonitride, or a high dielectric constant dielectric material. For example, the first dielectric layer 30 and the second dielectric layer 32 respectively include silicon nitride and silicon oxide, but not limited thereto. In a preferably embodiment, the top surface of the gate dielectric layer is for example higher than top surfaces of the gate electrode GE and the barrier layer 28, such that, the gate dielectric layer GD is allowable to entirely cover an arc sidewall of the protrusion 26a. The top surface of the barrier layer 28 is preferably higher than the top surface of the gate electrode GE, and a high difference between the top surfaces of the barrier layer 28 and the gate electrode GE is about ΔH1, ensuring the gate dielectric layer GD and the gate electrode GE at two sides of the barrier layer 28 without physically contacting with each other. Furthermore, the bottom surface of the gate dielectric layer GD is preferably coplanar with the bottom surfaces of the gate electrode GE, the barrier layer 28, and the upper dielectric layer 26, but is not limited thereto.

Further in view of FIG. 1, the semiconductor device 100 further includes a dielectric layer 10, a bottom semiconductor layer 18, a bottom dielectric layer 20, a dielectric layer 48, a trough hole OP1, and an opening OP2. The aforementioned source electrode SE, drain electrode DE, the gate electrode GE, the gate dielectric layer GD, the channel structure SS, the barrier layer 28, and the upper dielectric layer 26 are all disposed on the dielectric layer 10, and the dielectric layer 10 is disposed on a substrate (not shown in the drawings). The substrate for example includes a silicon substrate, a silicon-containing substrate, an epitaxial silicon substrate, a silicon-on-insulator (SOI) substrate, or a substrate made of other suitable materials, but not limited thereto. In addition, people skilled in the art should easily realize that any required active components and/or passive component may be further formed on the substrate or in the substrate due to product requirements. Precisely speaking, the bottom dielectric layer 18 is disposed between the bottom dielectric layer 20 and the source electrode SE in the vertical direction D1. The upper dielectric layer 26 is disposed between the dielectric layer 48 and the upper dielectric layer 26, and the drain electrode DE is disposed within the dielectric layer 48, but not limited thereto. It is noted that the through hole OP1 penetrates through the upper dielectric layer 26 and the gate electrode GE in the vertical direction D1, and the opening OP2 penetrates through the bottom dielectric layer 20 in the vertical direction D1, with the through hole OP1 directly connecting the opening OP2, and with the through hole OP1 having a relative greater diameter to completely overlap the opening OP2, but not limited thereto. Accordingly, the gate dielectric layer GD, the barrier layer 28 and a portion of the channel structure SS are sequentially disposed within the through hole OP1 in the horizontal direction D2 or in the horizontal direction D3 opposite to the horizontal direction D2, and another portion of the channel structure SS is disposed in the opening OP2. In this way, the channel structure SS further penetrates the bottom dielectric layer 20 in the vertical direction D1 to physically contact the bottom semiconductor layer 18. People in the art should easily realize that the through hole OP1 and the opening OP2 according to the present disclosure are not limited to the aforementioned type, and the through hole OP1 and the opening OP2 may have other different arrangements or shape based on practical product requirements.

In one embodiment, the source electrode SE, the gate electrode GE, and a drain electrode DE for example includes a multilayer structure. For example, the source electrode SE preferably includes a metal barrier layer 12, an electrode layer 14, and a metal barrier layer 16 stacked sequentially in the vertical direction D1. The gate electrode GE includes a metal barrier layer 22 and an electrode layer 24 stacked sequentially in the vertical direction D1, and barrier layer 28 physically contact the metal barrier layer 22 and the electrode layer 24 of the gate electrode GE at the same time. The drain electrode DE includes a metal barrier layer 42 and an electrode layer 44 stacked sequentially in the vertical direction D1. In other embodiments, the metal barrier layer 12, the metal barrier layer 16, the metal barrier layer 22, and/or the metal barrier layer 42 may be optionally omitted or further include a multilayer based on practical product requirements, but not limited thereto. In one embodiment, the metal barrier layer 12, the metal barrier layer 16, the metal barrier layer 22 and the metal barrier layer 42 may optionally include the same material or different materials like titanium, titanium nitride, tantalum, tantalum nitride, tungsten nitride, or other suitable metal barrier materials, and preferably all include but not limited to titanium nitride. Furthermore, the electrode layer 14, the electrode layer 24, and the electrode layer 44 may optionally include the same material or different materials like copper, aluminum, tungsten or other suitable low-resistance metal materials, and preferably all include but not limited to tungsten.

On the other hand, the channel structure SS precisely includes a channel layer 40 and an insulating layer 36 stacked in sequence in the horizontal direction D2 or in the horizontal direction D3, and the insulating layer 36 may be used to indirectly control the composition of the channel structure SS and/or support the channel structure SS. The channel layer 40 further includes a first semiconductor layer 34 and a second semiconductor layer 38 stacked sequentially in the horizontal direction D2 or the horizontal direction D3. The first semiconductor layer 34 is partially disposed in the through hole OP1, and partially disposed in the opening OP2, and the second semiconductor layer 38 is disposed in the through hole OP1, between the insulating layer 36 and the drain electrode DE. In the present embodiment, the first semiconductor layer 34 is around the second semiconductor layer 38 in the horizontal direction D2 and/or the horizontal direction D3, such that, the first semiconductor layer 34 will include an U-shape cross section as shown in FIG. 1, between the drain electrode DE and the bottom semiconductor layer 18 in the vertical direction D1. Accordingly, the first semiconductor layer 34 of the channel layer 40 physically contacts the second semiconductor layer 38 and the bottom semiconductor layer 18 at the same time, and the channel layer 40 is allowable to be electrically connected to the drain electrode DE and the source electrode SE while a threshold voltage is applied to the gate electrode GE. In one embodiment, the bottom semiconductor layer 18, and the first semiconductor layer 34 and the second semiconductor layer 38 of the channel layer 40 for example all include a semiconductor material like doped polysilicon, doped amorphous silicon, indium zinc oxide (IZO), aluminum zinc oxide (AZO) or indium gallium zinc oxide (IGZO), but is not limited thereto. Also, the materials of the first semiconductor layer 34, the second semiconductor layer 38 and the bottom semiconductor layer 18 may be optionally the same or different from each other. In another embodiment, the dielectric layer 10, the bottom dielectric layer 20, the upper dielectric layer 26, and the dielectric layer 48 for example all include a dielectric material like silicon oxide, silicon nitride, silicon oxynitride, or silicon carbonitride, or a high dielectric constant dielectric material, and preferably all include silicon oxide, but not limited thereto.

With these arrangements, the channel structure SS of the semiconductor device 100 in the present embodiment presents in a columnar structure extending in the vertical direction D1, and the gate dielectric layer GD presents in an annular structure surrounding outside the channel structure SS and is between the gate electrode GE and the channel structure SS in the horizontal direction D2. Then, the drain electrode DE, the gate dielectric layer GD, the gate electrode GE, the channel structure SS, and the source electrode SE together form a three-dimensional (3D) transistor component, with the channel structure SS serving as the vertical channel structure of the 3D transistor component, and with the gate electrode GE surrounding outside the channel structure SS to function like a gate-all-around (GAA) component. According to the semiconductor device 100 of the present embodiment, the location of the barrier layer 28 may be self-aligned with the protrusion 26a of the upper dielectric layer 26, due to the arrangement of the upper dielectric layer 26, so that, it is effectively on isolating the gate dielectric layer GD from directly contacting the metal materials, avoiding the dielectric material of the gate dielectric GD from being reacted with the metal material of the gate electrode GE and easily producing high-resistance products. In this way, the component performance of the gate electrode GE and the channel structure SS will be dramatically improved. Following these, the semiconductor device 100 of the present embodiment may be upwardly or downwardly electrically connected to other required active components and/or passive component optionally through any connecting components in the subsequent processes, with the arrangements of the upper dielectric layer 26 and the barrier layer 28 to improve the component performances of the gate electrode GE and the channel structure SS, to achieve better function and operation.

In order to make people skilled in the art of the present disclosure easily understand the semiconductor device of the present disclosure, the fabricating method of the semiconductor device 100 in the present disclosure will be further described below.

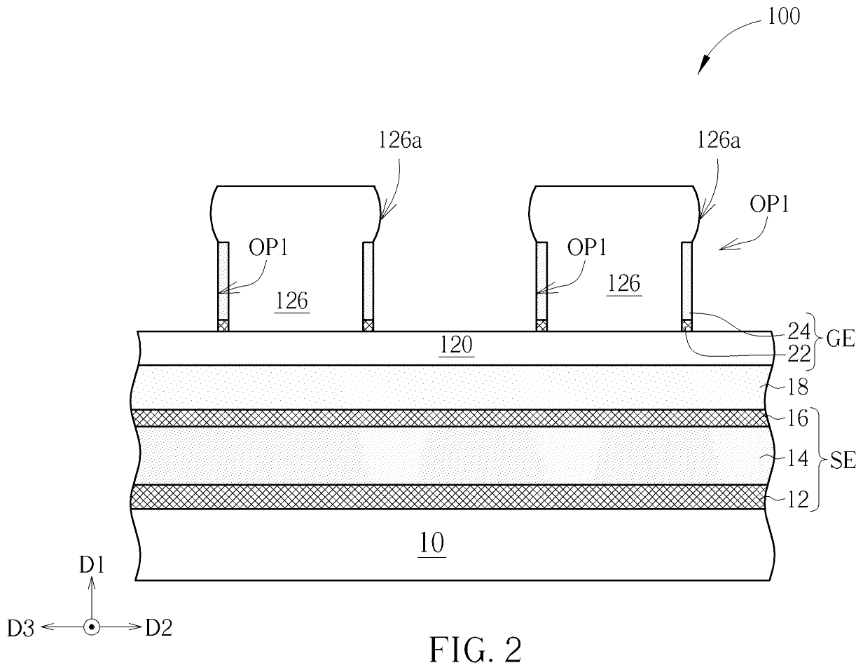

Please refer to FIG. 2 to FIG. 8, illustrating schematic diagrams of a fabricating method of the semiconductor device 100 according to one embodiment in the present disclosure. Firstly, as shown in FIG. 2, the source electrode SE, the bottom semiconductor layer 18, a bottom dielectric material layer 120, the gate electrode GE, and an upper dielectric material layer 126 are sequentially formed on the dielectric layer 10, and next, the through hole OP1 is formed to sequentially penetrate through the upper dielectric material layer 26 and the gate electrode GE, to partially expose the bottom dielectric material layer 120. The fabrications of the upper dielectric material layer 126 and the gate electrode GE include but not limited to the following steps. Firstly, a barrier material layer (not shown in the drawings) and an electrode material layer (not shown in the drawings) are sequentially formed on the bottom dielectric material layer 120, followed by patterning the electrode material layer and the barrier material layer, to form the metal barrier layer 22 and the electrode layer 24 stacked in sequence in the vertically direction D1 to together form the gate electrode GE. Then, a dielectric material layer (not shown in the drawings) is formed on the gate electrode GE to fill in the space therebetween, and an etching process, such as a wet etching process, a dry etching process or sequentially performed a wet etching process and a dry etching process, is performed through a mask layer (not shown in the drawings), to partially remove the dielectric material layer and the gate electrode GE to form the through hole OP1 sequentially penetrating the dielectric layer and the gate electrode GE in the vertically direction D1, and to form the upper dielectric layer 126 at the same time. After that, the mask layer is completely removed.

It is noted that, before performing the etching process, since the factors like the different etching selectivity between the dielectric material layer and the electrode material layer, as well as the rounding corners, the upper dielectric material layer 126 covering on the gate electrode GE forms the arc sidewall 126a, and also, the recess portion is formed at the boundary between the arc sidewall 126a and the gate electrode GE, as shown in FIG. 2. In one embodiment, the metal barrier layer 12, the metal barrier layer 16, and the metal barrier layer 22 may include the same or different barrier material like titanium, titanium nitride, tantalum, tantalum nitride, tungsten nitride or other suitable barrier material layers, and preferably all include titanium nitride, and the electrode layer 14, and the electrode 24 may include the same or different electrode material like copper, aluminum, tungsten or other suitable low-resistance metal materials, and preferably all include tungsten, but not limited to. The dielectric layer 10, the bottom dielectric material layer 120, and the upper dielectric material layer 126 for example all include a dielectric material like silicon oxide, silicon nitride, silicon oxynitride, or silicon carbonitride, or a high dielectric constant dielectric material, and preferably all include silicon oxide, but not limited thereto. Furthermore, the bottom semiconductor layer 18 for example includes a semiconductor material like doped polysilicon, doped amorphous silicon, indium zinc oxide, aluminum zinc oxide or indium gallium zinc oxide, but is not limited thereto.

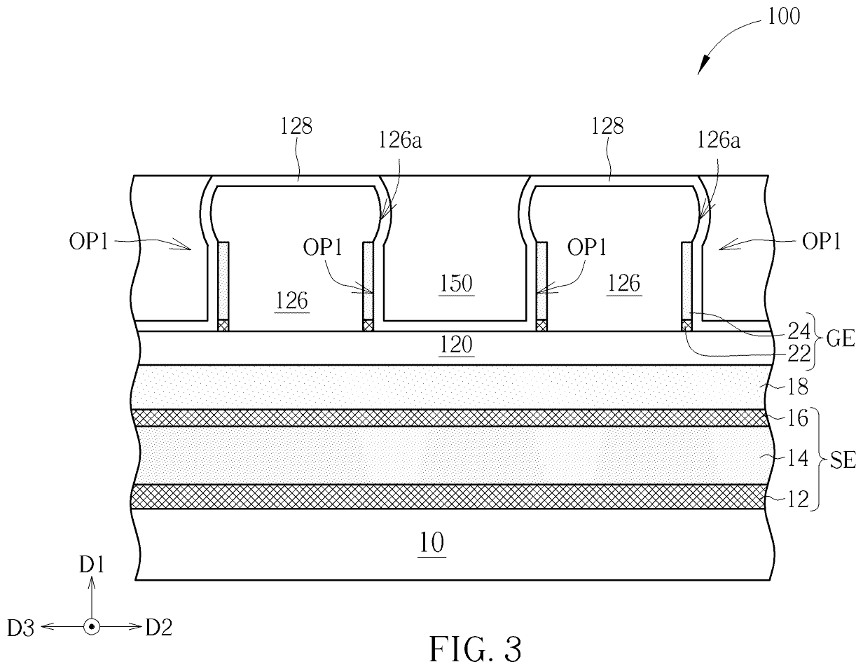

As shown in FIG. 3, a film forming process such as a chemical vapor deposition process, a physical vapor deposition process or other suitable approaches is performed to form a barrier material layer 128, being partially formed within the through hole OP1 and partially formed outside the through hole OP1, with the barrier material layer 128 conformally covering the top surface of the upper dielectric material layer 126, the arc sidewall 126a, the sidewall of the gate electrode GE, and the exposed top surface of the bottom dielectric material layer 120. Then, performing a deposition and etching back process, to form a sacrificial layer 150 filled up the through hole OP1, with the barrier material layer 128 covering on the upper dielectric material layer 126 and the sacrificial layer 150 being coplanar. In one embodiment, the barrier material layer 128 for example includes titanium, titanium nitride, tantalum, tantalum nitride, tungsten nitride, or other suitable barrier material, with the material thereof being preferably the same as that of the aforementioned metal barrier layer 12, the metal barrier layer 16 and the metal barrier layer 22, for example all including titanium nitride, and the sacrificial layer 150 for example includes a dielectric material like silicon oxide or silicon oxynitride, but not limited thereto.

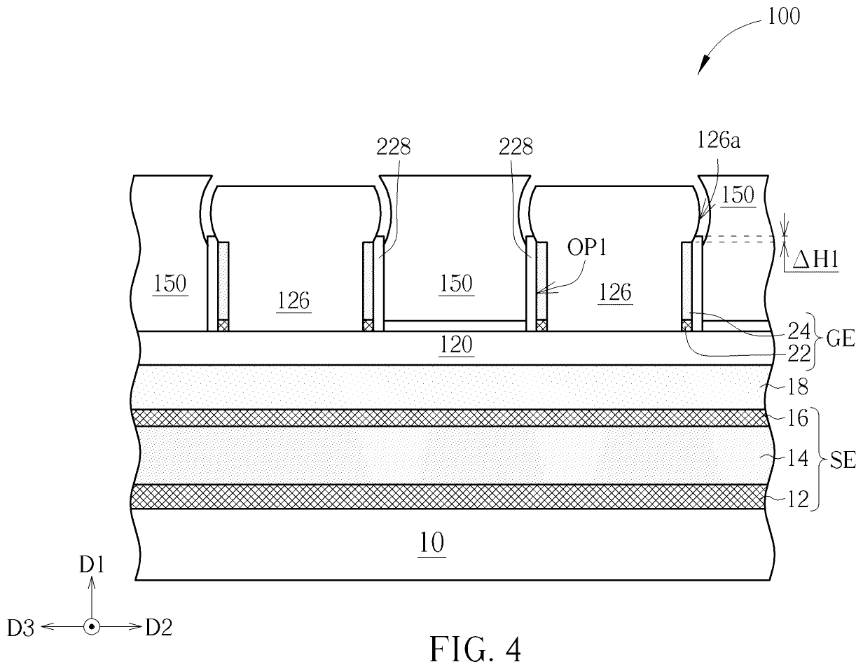

As shown in FIG. 4, a wet etching process is performed through the coverage of the sacrificial layer 150, to remove the barrier material layer 128 covering on the top surface and the arc sidewall 126a of the upper dielectric material layer 126, and to form a barrier material layer 228 with an U-shaped cross-section. The barrier material layer 228 physically contacts the metal battier layer 22 and the electrode layer 24 of the gate electrode GE, and the top surface of the barrier material layer 228 is preferably higher than the top surface of the gate electrode GE, to partially fill in the recess portion between the arc sidewall 126a and the gate electrode GE. In one embodiment, a height difference between the top surface of the barrier material layer 228 and the top surface of the gate electrode GE is about ΔH1, but is not limited thereto.

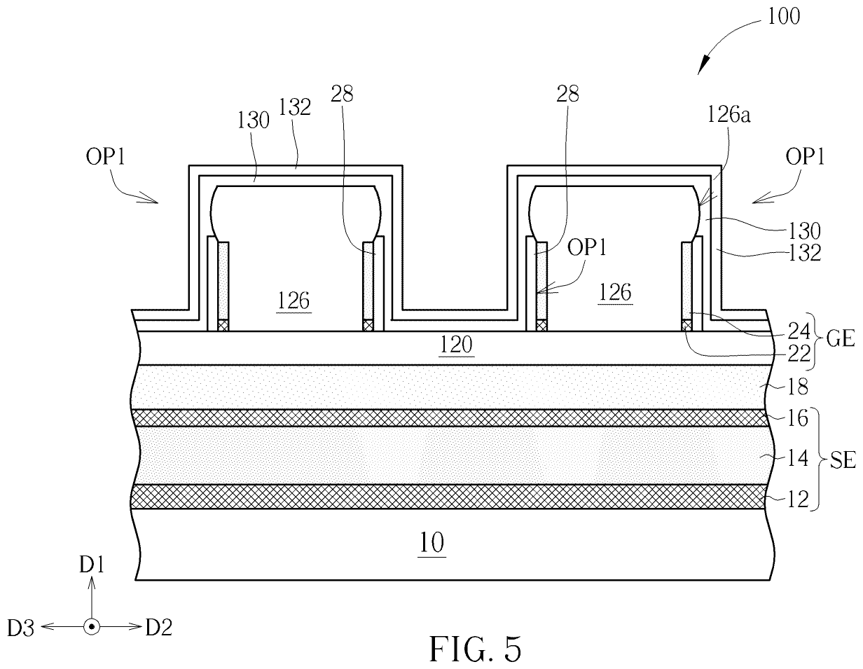

As shown in FIG. 5, a dry etching process is performed through the blocking of the arc sidewall 126a of the upper dielectric material layer, with the barrier material layer 228 covering on the vertical sidewall, to completely remove the sacrificial layer 150 and the barrier material layer 228 underneath, and to form the barrier layer 28 as shown in FIG. 1. Then, another film forming process such as a chemical vapor deposition process, a physical vapor deposition process or other suitable approaches is performed, to sequentially form a first dielectric material layer 130 and a second dielectric material layer 132 partially within the through hole OP1 and partially outside the through hole OP1. That is, the first dielectric material layer 130 and the second dielectric material layer 132 are all formed by conformally covering the top surface of the upper dielectric material layer 126, the arc sidewall 126a, the sidewall of the barrier layer 28, and the exposed top surface of the bottom dielectric material layer 120, with the first dielectric material layer 130 further filling in the rest space of the recess portion. In one embodiment, the first dielectric material layer 130 and the second dielectric material layer 132 for example all include a dielectric material like silicon oxide, silicon nitride, silicon oxynitride or silicon carbonitride, or a high dielectric constant dielectric material. For example, the first dielectric material layer 130 and the second dielectric material layer 132 respectively include silicon nitride and silicon oxide, but not limited thereto.

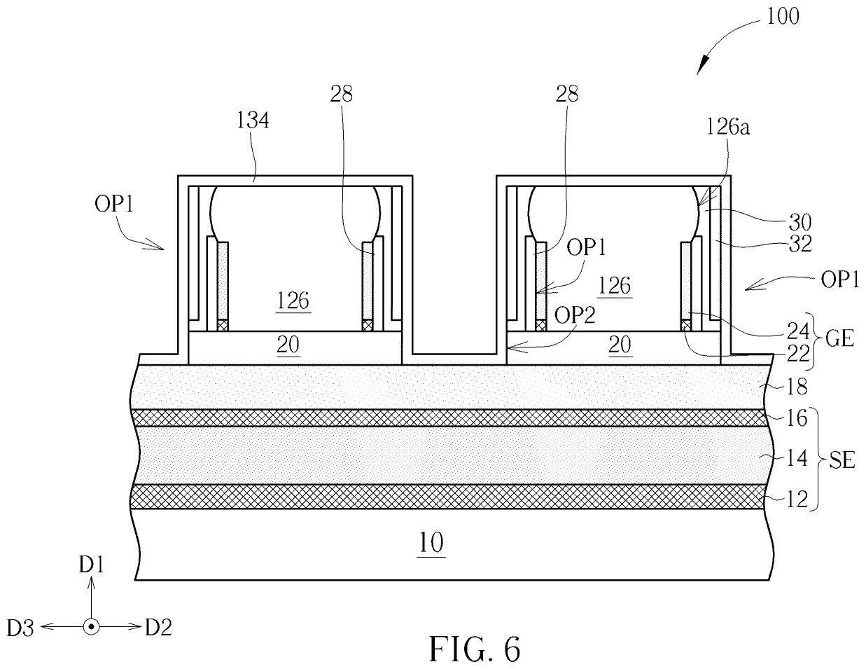

As shown in FIG. 6, an etching process is performed through the covering of the second dielectric material layer 132 and the first dielectric material layer 130, to remove the second dielectric material layer 132 and the first dielectric material layer 130 outside the through hole OP1, and the second dielectric material layer 132 and the first dielectric material layer 130 at the bottom of the through hole OP1, and to form the second dielectric layer 32 and the first dielectric layer 30, thereby forming the gate dielectric layer GD and partially exposing the bottom dielectric material layer 120 through the through hole OP1. Also, during the etching process, the bottom dielectric material layer 120 exposed from the through hole OP1 is further removed downwardly through the through hole OP1, to form the bottom dielectric layer 20 and the opening OP2 penetrating through the bottom dielectric layer 20, with the bottom semiconductor layer 18 being partially exposed from the opening OP2.

It is also noted that, the opening OP2 is overlapped with the through hole OP1 in the vertical direction D1, and a projection area of the opening OP2 in the vertical direction D1 is smaller than a projection area of the through hole OP1 in the vertical direction D1. Then, the opening OP2 may be direction connected to the through hole OP1, but is not limited thereto. Next, further in view of FIG. 6, another film forming process, such as a chemical vapor deposition process, a physical vapor deposition process or other suitable approaches, is performed to form a first semiconductor material layer 134 partially within the opening OP2, partially within the through hole OP1, and partially outside the through hole OP1, such that, the first semiconductor material layer 134 may be conformally formed on the top surface of the upper dielectric material layer 126, the second dielectric layer 32, the sidewall of the bottom dielectric layer 20, and the bottom semiconductor layer 18. In one embodiment, the first semiconductor material layer 134 for example a semiconductor material like doped polysilicon, doped amorphous silicon, indium zinc oxide, aluminum zinc oxide or indium gallium zinc oxide, and preferably includes the same semiconductor material as the bottom semiconductor layer 18, but not limited thereto.

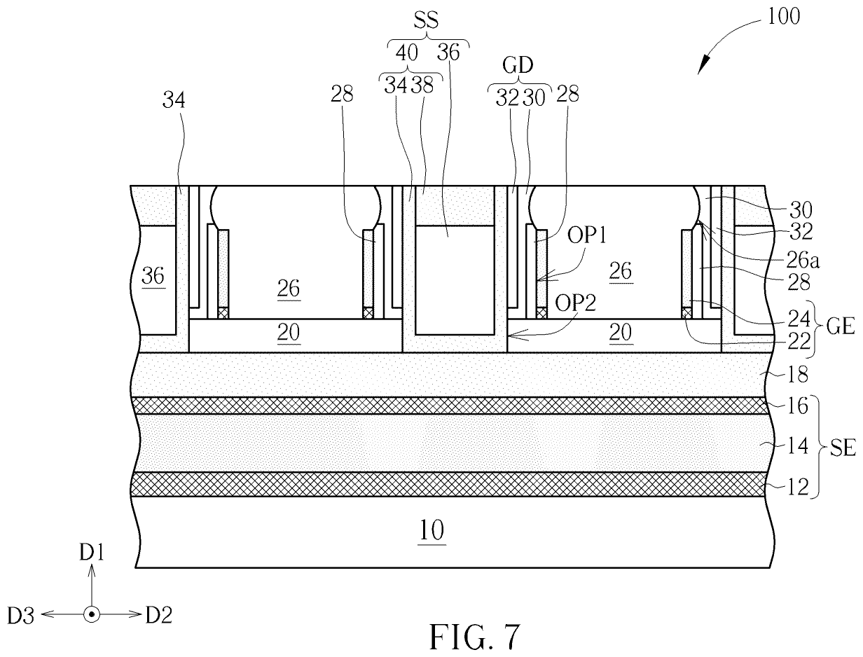

As shown FIG. 7, after forming the opening OP2, a deposition and an etching back process is performed, to firstly form an insulating material layer (not shown in the drawings) filling up the opening OP2 and the through hole OP1, and further covering on the first semiconductor material layer 134 outside the through hole OP1. Then, the insulating material layer is partially removed by removing the insulating material layer outside the opening OP2 and the through hole OP1, and by partially the insulating material layer within the through hole OP1, to form the insulating layer 36. The top surface of the insulating layer 36 is for example lower than the top surface of the gate electrode GE. In one embodiment, the insulating material layer for example includes a dielectric material like silicon oxide, silicon nitride, silicon oxynitride or silicon carbonitride, and preferably includes silicon oxide, but not limited thereto.

Next, further in view of FIG. 7, a second semiconductor material layer (not shown in the drawings) is formed to fill up the through hole OP1 and further on the first semiconductor material layer 134 outside the through hole OP1. Then, a planarization process such as a chemical polishing process or other suitable process is performed, to simultaneously remove the second semiconductor material layer, the first semiconductor material layer 134 outside the through hole OP1, to form the second semiconductor layer 38 and the first semiconductor layer 34. Accordingly, the first semiconductor layer 34, and the second semiconductor layer 38 sequentially stacked in the horizontal direction D2 or in the horizontal direction D3 within the through hole OP1 together form the channel layer 40, and the channel layer 40 and the insulating layer 36 together form the channel structure SS. In one embodiment the second semiconductor material layer for example include a semiconductor material like doped polysilicon, doped amorphous silicon, indium zinc oxide, aluminum zinc oxide or indium gallium zinc oxide, and preferably includes the same material as the first semiconductor material layer 134 and the bottom semiconductor layer 18, but not limited thereto. On the other hands, the second dielectric layer 32, the first dielectric layer 30 and the upper dielectric material layer 126 are also partially removed during the planarization process, to form the second dielectric layer 32, the first dielectric layer 30 and the upper dielectric layer 26 as shown in FIG. 1. The upper dielectric layer 26 is partially protruded toward the channel structure SS and is sandwiched between the drain electrode DE and the gate electrode GE, to form the protrusion 26a. The first dielectric layer 30 and the second dielectric layer 32 together form the gate dielectric layer GD of the semiconductor device 100. Accordingly, the gate dielectric layer GD, the upper dielectric layer 26 will therefore include coplanar top surfaces, which is leveled with the top surface of the channel structure SS.

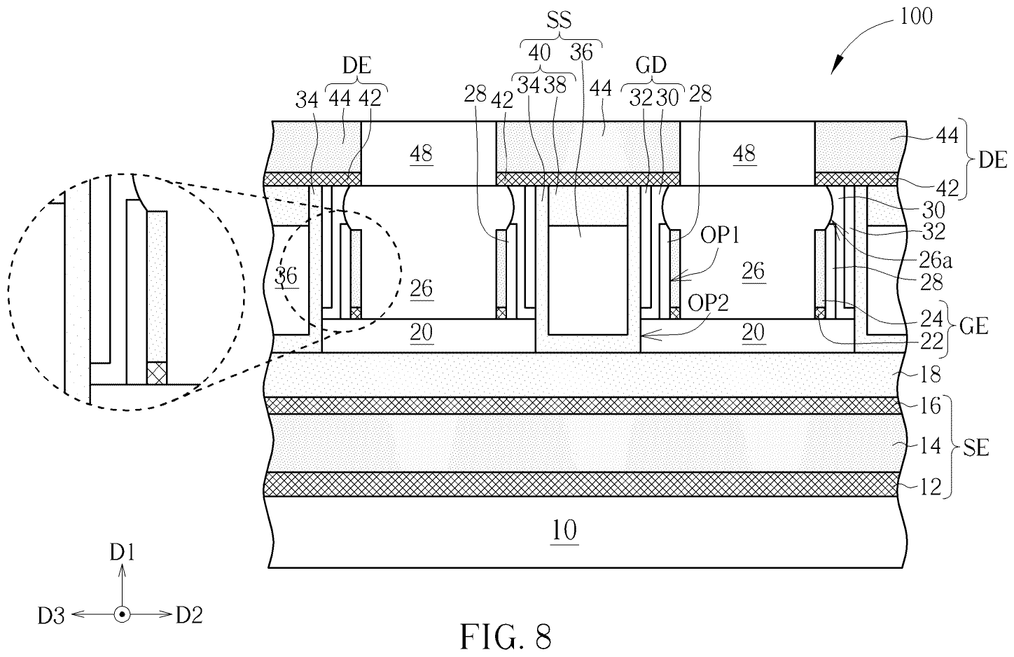

As shown in FIG. 8, after forming the channel structure SS, a drain electrode DE is continuously formed, with the drain electrode DE being formed on the channel structure SS, the gate dielectric layer GD and the protrusion 26a of the dielectric layer 26. Following these, the dielectric layer 48 is formed, to obtain the semiconductor device 100 as shown in FIG. 1, with the first semiconductor layer 34 of the channel layer 40 physically contacting the second semiconductor layer 38 and the bottom semiconductor layer 18 at the same time, and the channel layer 40 is allowable to be electrically connected to the drain electrode DE and the source electrode SE. Through these performances, the fabricating process of the semiconductor device 100 is completed.

According to the fabricating process of the present embodiment, the source electrode SE is firstly formed on the dielectric layer 10, and the gate electrode GE is next formed on the source electrode SE. Then, the through hole OP1 is formed penetrating through the upper dielectric material layer 126 and the gate electrode GE in the vertical direction D1, and the barrier layer 28 is formed through a self-alignment of the arc sidewall of the upper dielectric material layer 126, with the barrier layer 28 physically contacting the metal barrier layer 22 and the electrode layer 24 of the gate electrode GE, and having a top surface higher than the gate electrode GE. After that, the gate dielectric layer GD and the channel structure SS are sequentially formed within the through hole OP1, followed by forming the drain electrode DE on the channel structure SS and the gate dielectric layer GD. With these performances, the channel structure SS is at least partially within the gate electrode GE, between the drain electrode DE and the source electrode SE, to electrically connect the drain electrode DE and the source electrode SE. Also, the gate dielectric layer GD is isolated from the metal material due to the arrangement of the barrier layer 28, avoid the dielectric material of the gate dielectric layer GD from being reacted with the metal material of the gate electrode GD to generate high-resistant product. In this way, the semiconductor device 100 fabricated in the fabricating process of the present embodiment enables to obtain the gate electrode GE and the channel structure SS with better component performance, so that, the operation and the function of the semiconductor device 100 is therefore enhanced.

People in the art should fully realize that the semiconductor device and the fabricating method thereof are not limited to the aforementioned embodiment and may include other examples or may be achieved through other strategies to meet practical product requirements. The following description will detail the different embodiments of the semiconductor device and fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

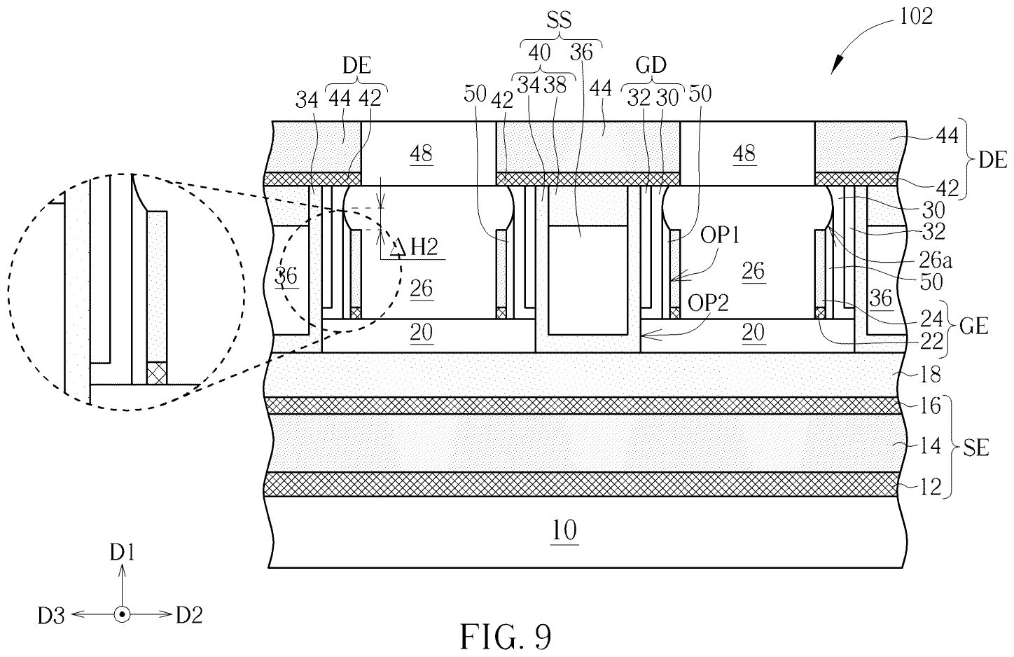

Please refer to FIG. 9, illustrating a schematic diagram of a cross-sectional view of a semiconductor device 102 according to the second embodiment of the present disclosure. The structure of the semiconductor device 102 according to the present embodiment is substantially the same as the structure of the semiconductor device 100 according to the aforementioned first embodiment, which also including the source electrode SE, the gate electrode GE, the drain electrode DE, the channel structure SS, the gate dielectric layer GD, and the upper dielectric layer 26, and all similarities will not be redundantly described hereinafter. The semiconductor device 102 of the present embodiment and the aforementioned first embodiment is mainly in that the protrusion 26a of the upper dielectric layer 26 completely covers the top surface of the barrier layer 50.

Precisely speaking, the etching conditions of the wet etching process of the present embodiment is further adjusted, to partially remain the barrier material layer 128 covering on the arc sidewall 126a of the upper dielectric material layer 126 as shown in FIG. 4, to form a barrier layer 50. Accordingly, the recess portion at the boundary between the gate electrode GE and the protrusion 26a of the upper dielectric layer 26 is completely filled by the barrier layer 50, as shown in FIG. 9. The top surface of the barrier layer 50 is preferably higher than the top surface of the gate electrode GE, and a height difference between the top surface of the barrier layer 50 and the top surface of the gate electrode GE is about ΔH2. With these arrangements, the gate dielectric layer GD and the gate electrode GE are still both in physical contact with each other due to the arrangement of the barrier layer 50, thereby avoiding the dielectric material of the gate dielectric GD from being reacted with the metal material of the gate electrode GE and easily producing high-resistance products. According to the semiconductor device 102 of the present embodiment, the forming position of the barrier layer 50 may also be self-aligned with the protrusion 26a of the upper dielectric layer 26, based on the arrangement of the upper dielectric layer 26. Also, the barrier layer 50 is allowable to further isolate the gate dielectric layer GD from directly contacting the metal materials, to improve the component performance of the channel structure SS and the gate electrode GE, and to optimize the operation and the function of the semiconductor device 102 thereby.

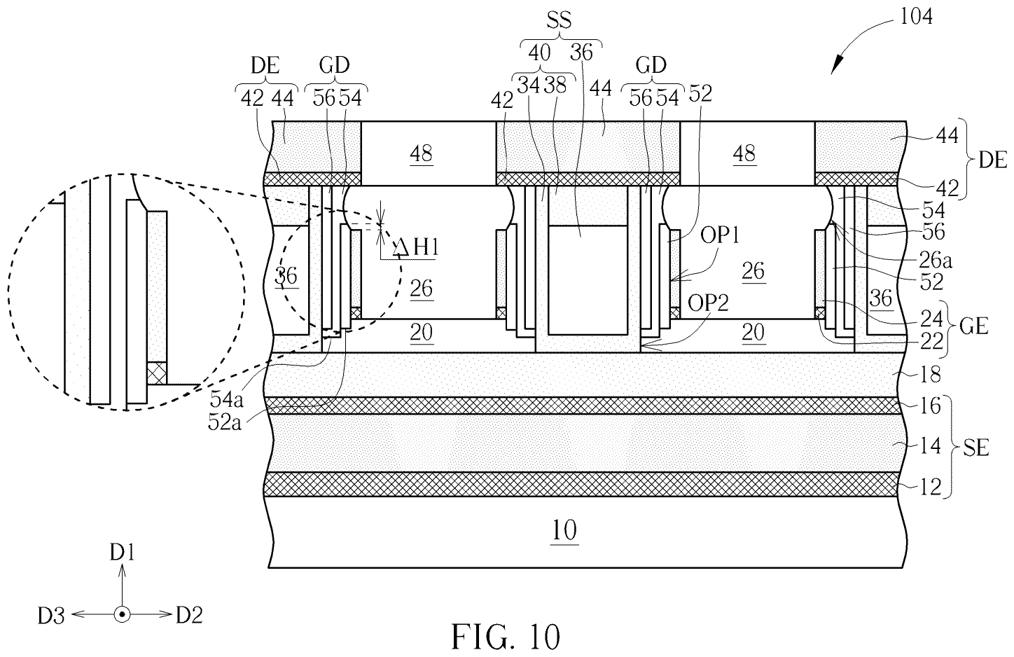

As shown in FIG. 10, illustrating a schematic diagram of a cross-sectional view of a semiconductor device 104 according to the third embodiment of the present disclosure. The structure of the semiconductor device 104 according to the present embodiment is substantially the same as the structure of the semiconductor device 100 according to the aforementioned first embodiment, which also including the source electrode SE, the gate electrode GE, the drain electrode DE, the channel structure SS, the gate dielectric layer GD, and the upper dielectric layer 26, and all similarities will not be redundantly described hereinafter. The semiconductor device 102 of the present embodiment and the aforementioned first embodiment is mainly in that a bottom surface 52a of a barrier layer 52 is lower than the bottom surface of the gate electrode GE and is higher than the bottom surface of the gate dielectric layer GD.

Precisely speaking, an etching process of the present embodiment is performed before forming the barrier material layer 128 as shown in FIG. 3, and before forming the first dielectric material layer 130 and the second dielectric material layer 132, with the bottom dielectric layer 20 being slightly etched through the through hole OP1, so that, the barrier layer 52 and the first dielectric layer 54 formed subsequently are both partially extended into the bottom dielectric layer 20. The bottom surface 52a of the barrier layer 52 is lower than the bottom surface of the gate electrode GE and is higher than the bottom surface 54a of the first dielectric layer 54, as shown in FIG. 10.

The barrier layer 52 of the present embodiment also includes a top surface being higher than the gate electrode GE, such that, the gate dielectric layer GD and the gate electrode GE are not physically in contact with each other, avoiding the dielectric material of the gate dielectric GD from being reacted with the metal material of the gate electrode GE and easily producing high-resistance products. According to the semiconductor device 104 of the present embodiment, the forming position of the barrier layer 52 may also be self-aligned with the protrusion 26a of the upper dielectric layer 26, based on the arrangement of the upper dielectric layer 26. Also, the barrier layer 52 is allowable to further isolate the gate dielectric layer GD from directly contacting the metal materials, to improve the component performance of the channel structure SS and the gate electrode GE, and to optimize the operation and the function of the semiconductor device 104 thereby.

Overall speaking, according to the semiconductor device and the fabricating method thereof, a protrusion is additionally formed on the upper dielectric layer which is disposed between the drain electrode and gate electrode, with the protrusion being protruding toward the channel structure. Then, the forming position of the barrier layer will be self-aligned with the protrusion of the upper dielectric layer, to effectively isolate the gate dielectric layer from metal materials. In this way, the arrangement of the barrier layer enables to prevent the dielectric material of the gate dielectric layer from directly contacting the metal material of the gate electrode and easily producing high-resistance products, and to improve the functions and performance of the gate electrode and the channel structure, so as to optimize the operation and the function of the semiconductor device thereby.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a source electrode;
a drain electrode, the source electrode and the drain electrode being stacked;
a gate electrode disposed between the drain electrode and the source electrode;
a channel structure, disposed between the drain electrode and the source electrode and connected the drain electrode and the source electrode;
a gate dielectric layer, disposed between the channel structure and the gate electrode;
a barrier layer, disposed between the gate electrode and the gate dielectric layer; and
an upper dielectric layer, disposed between the drain electrode and the source electrode, wherein the upper dielectric layer comprises a protrusion protruding toward the channel structure and sandwiched between the gate electrode and the drain electrode, and the protrusion at least covers a part of a top surface of the barrier layer.

2. The semiconductor device according to claim 1, wherein the protrusion completely covers the top surface of the barrier layer.

3. The semiconductor device according to claim 1, wherein the gate dielectric layer contacts the top surface of the barrier layer.

4. The semiconductor device according to claim 1, wherein the top surface of the barrier layer is higher than a top surface of the gate electrode.

5. The semiconductor device according to claim 1, wherein a bottom surface of the barrier layer is lower than a bottom surface of the gate electrode, and is higher than a bottom surface of the gate dielectric layer.

6. The semiconductor device according to claim 2, wherein a boundary between the protrusion and the gate electrode comprises a recess portion, and the barrier layer is disposed within the recess portion.

7. The semiconductor device according to claim 1, wherein top surfaces of the gate electrode and the barrier layer are lower than a top surface of the gate dielectric layer.

8. The semiconductor device according to claim 1, wherein the gate dielectric layer further comprises:
a first dielectric layer, disposed between the barrier layer and the channel structure, to physically contact the protrusion; and
a second dielectric layer, disposed between the first dielectric layer and the channel layer.

9. The semiconductor device according to claim 1, wherein the channel structure comprises a channel layer and an insulating layer disposed in sequence, the channel layer surrounding the insulating layer.

10. The semiconductor device according to claim 1, wherein the gate electrode, the drain electrode, and the source electrode respectively comprises:
an electrode layer; and
a metal barrier layer, disposed under the electrode layer, wherein the electrode layers of the drain electrode, the source electrode and the gate electrode comprise a same metal material, and the metal barrier layers of the drain electrode, the source electrode and the gate electrode comprise a same metal barrier material.

11. The semiconductor device according to claim 10, wherein the barrier layer physically contacts the metal barrier layer and the electrode layer of the gate electrode.

12. The semiconductor device according to claim 1, further comprising:
a bottom dielectric layer, disposed between the source electrode and the gate electrode, to physically contact a bottom surface of the upper dielectric layer, wherein a portion of the channel structure is disposed within the bottom dielectric layer.

13. A method of fabricating a semiconductor device, comprising:
forming a source electrode, a gate electrode, and a drain electrode stacked in sequence;
forming a channel structure between the drain electrode and the source electrode, to connect the drain electrode and the source electrode;
forming a gate dielectric layer, between the channel structure and the gate electrode; and
forming an upper dielectric layer between the drain electrode and the source electrode, wherein the gate electrode is formed within the upper dielectric layer, the upper dielectric layer comprises a protrusion protruding toward the channel structure and is sandwiched between the gate electrode and the drain electrode, and the gate electrode is under the protrusion.

14. The method of fabricating the semiconductor device according to claim 13, further comprising:
before forming the gate electrode, forming a bottom dielectric layer on the source electrode;
forming an upper dielectric material layer on the gate electrode and the bottom dielectric layer, to cover a top surface of the gate electrode; and
forming a through hole penetrating through the upper dielectric material layer and the gate electrode in a vertical direction, wherein the upper dielectric material comprises an arc sidewall, and a boundary between the arc sidewall and the gate electrode comprises a recess portion.

15. The method of fabricating the semiconductor device according to claim 14, further comprising:
before forming the channel structure, forming a barrier layer in the through hole, below the arc sidewall; and
forming the gate dielectric layer and the channel structure in the through hole, wherein the barrier layer is formed between the gate dielectric layer and the gate electrode in a horizontal direction.

16. The method of fabricating the semiconductor device according to claim 15, wherein the barrier layer is filled in the recess portion.

17. The method of fabricating the semiconductor device according to claim 15, wherein the barrier layer and a portion of the gate dielectric layer is filled in the recess portion.

18. The method of fabricating the semiconductor device according to claim 14, forming the barrier layer further comprising:
forming a barrier material layer, partially within the through hole and partially outside the through hole;
forming a sacrificial layer, filling in the through hole;
removing the barrier material layer covering on the upper dielectric layer, to form the barrier layer; and
completely removing the sacrificial layer.

19. The method of fabricating the semiconductor device according to claim 14, forming the channel structure further comprising:
sequentially forming a first semiconductor material layer and an insulating material layer in the through hole;
partially removing the insulating material layer and the first semiconductor material layer, to form an insulating layer and a first semiconductor layer;
forming a second semiconductor material layer in the through hole; and
partially removing the second semiconductor material layer to form the second semiconductor layer, wherein the channel structure comprises a channel layer and the insulating layer stacked in sequence in a horizontal direction, and the channel layer comprises the first semiconductor layer and the second semiconductor layer.

20. The method of fabricating the semiconductor device according to claim 14, forming the gate dielectric further comprising:
forming a first dielectric material layer and a second dielectric material layer, partially within the through hole and partially outside the through hole; and
partially removing the second dielectric material layer and the first dielectric material layer, to form a second dielectric layer and a first dielectric layer, wherein the gate dielectric layer comprises the first dielectric layer and the second dielectric layer.
